(19) United States
(12) Patent Application Publication
(10) Pub. No.: US 2015/0020879 A1
(43) Pub. Date: Jan. 22, 2015

(54) LAMINATE AND ORGANIC EL ELEMENT, WINDOW, AND SOLAR BATTERY MODULE USING SAME

(71) Applicant: Hitachi, Ltd., Tokyo (JP)

(72) Inventors: Yuichi Sawai, Tokyo (JP); Takashi Naito, Tokyo (JP); Takuya Aoyagi, Tokyo (JP); Tadashi Fujieda, Tokyo (JP); Hajime Murakami, Tokyo (JP); Hiroshi Yoshida, Tokyo (JP); Masahiko Ogino, Tokyo (JP); Akihiro Miyauchi, Tokyo (JP)

(73) Assignee: Hitachi, Ltd., Tokyo (JP)

(21) Appl. No.: 14/369,056

(22) PCT Filed: Nov. 21, 2012
(86) PCT No.: PCT/JP2012/080120

§ 371 Date: Jun. 26, 2014

(30) Foreign Application Priority Data
Dec. 26, 2011 (JP) 2011-282621

(51) Int. Cl. H01L 31/048; H01L 51/52

(52) U.S. Cl. CPC H01L 31/0481; H01L 51/524
USPC 136/256; 428/435; 428/412

(57) ABSTRACT

To improve the gas barrier property of a laminate containing a substrate containing resin or rubber and oxide glass. A laminate 8 comprising a substrate 9 containing resin or rubber and oxide glass 10 formed at least on one surface of the substrate, in which the oxide glass softens and fluidizes at a temperature equal to or lower than the softening temperature of the substrate and adheres to the substrate.

### TECHNICAL FIELD

The present invention relates to a laminate and an organic EL element, a window, and a solar battery module using the laminate.

### BACKGROUND ART

An organic compound, which ranges widely, has the advantages that it can easily adjust the functional capability, the physical properties, and the like to an object, is lightweight, and is likely to be formed at a relatively low temperature in comparison with another material; but has disadvantages such as a low mechanical strength. Meanwhile, glass: is excellent in mechanical strength and chemical stability and can exhibit various functions in comparison with an organic compound; but has the disadvantages of being sensitive to shock and fragile. In order to compensate the mutual disadvantages therefore, various composite materials produced by combining organic compounds with glass have been invented.

As a laminate (gas barrier sheet, for example) comprising glass, an oxide, or a nitride and an organic polymer, a substance produced by forming a thin film comprising an oxide or a nitride on an organic polymer film comprising a polyester or a polyamide by a method such as sputtering, vapor deposition, CVD, or a sol-gel method is proposed variously.

In Patent Literature 1, a gas barrier laminate produced by sequentially stacking a barrier layer comprising a metal or an inorganic compound and being formed by vacuum vapor deposition method and an organic layer comprising an organic compound at least on one surface of a polymer film is disclosed.

### CITATION LIST

### Patent Literature

Patent Literature 1: Japanese Unexamined Patent Publication No. 2008-265255

### SUMMARY OF INVENTION

### Technical Problem

The problems in the case of manufacturing a laminate by a vapor deposition method, a sputtering method, or a CVD method are that generally a film having a thickness of only tens of nanometers can be formed, the laminate is not perfectly dense, and hence a trifle amount of gas can still permeate the laminate.

An object of the present invention is to improve a gas barrier property.

### Solution to Problem

In order to attain the above object, the present invention is characterized by a laminate comprising a substrate containing resin or rubber and oxide glass formed at least on one surface of the substrate, wherein the oxide glass softens and fluidizes at a temperature not higher than the softening temperature of the substrate and adheres to the substrate.

### Advantageous Effects of Invention

The present invention makes it possible to improve a gas barrier property.

### BRIEF DESCRIPTION OF DRAWINGS

FIG. 1 shows a DTA curve of glass.

FIG. 2 shows an image of a process of forming an oxide layer on a polyimide film.

FIG. 3 shows the SEM images of laminate interfaces.

FIG. 4 is a schematic view showing the structure of an organic EL element used in experiment.

FIG. 5 is a graph showing the changes of the brightness of organic EL elements using various kinds of gas barrier films.

FIG. 6 is a view showing an image of a resin window.

FIG. 7 is a sectional view of the resin window taken on line A-A.

FIG. 8 has schematic views showing the manufacturing processes of the resin window.

FIG. 9 is a graph showing the transmittances of oxide glass layers.

FIG. 10 is a view showing the structure of a solar battery module.

### DESCRIPTION OF EMBODIMENTS

The present invention: relates to a gas barrier laminate; and is characterized by a laminate manufactured by forming oxide glass continuously in a layer at least on one surface of a substrate containing resin or rubber (hereunder referred to as a resin or the like), wherein the oxide glass softens and fluidizes at a temperature equal to or lower than the softening temperature of the resin or the like and adheres to the resin or the like. Further, the oxide glass contains at least two kinds of Te, P, and V and Ag. The reason is that generally the softening point of glass containing at least two kinds of Te, P, and V and Ag is low.

When a substrate has a sheet-shape, it is possible to give a gas barrier property by forming an oxide glass layer at least on one surface. The present invention can apply even when a substrate has a certain thickness and, in a word, it is only necessary to form an oxide glass layer on a surface for interrupting the transition of a gas.

In a laminate according to the present invention: particles of oxide glass containing at least two kinds of Te, P, and V and Ag are placed on a substrate containing a resin or the like; and successively the substrate is coated by heating the laminate at a temperature not lower than the melting point of the glass but not higher than the melting point of the resin or the like and softening and fluidizing (melting) the glass particles. This is because the melting point can be lowered by using oxide glass having a composition containing at least two kinds of Te, P, and V and Ag even though environmentally harmful elements such as Pb and Bi are not used.

A method for adhering glass particles before softening to a substrate and a method for heating them are not particularly limited and any methods can be used as long as the methods are the methods of heating a laminate in the state of bringing glass particles into contact with a substrate. Since a substrate comprising a resin or the like can be coated with once-melted glass thereby, it is possible to increase the denseness of the glass and improve the gas barrier property of a laminate. Further, since a substrate can be coated only by softening glass particles unlike a vapor deposition method or the like, it is possible to apply a thick coat to the substrate by softening the glass particles in the state of depositing the glass particles more than normal. By so doing too, it is possible to further improve the gas barrier property of a laminate. For example, when the particles of glass are processed into slurry and sprayed onto a substrate or are processed into paste and printed on a substrate and are subjected to a heating process, the thickness of the oxide layer of a laminate comes to be about 500 nm to 50 μm that is equivalent to the thickness of a film formed by spraying or printing. Furthermore, the thickness of an oxide layer formed by, paste coating comes to be about 50 μm to 300 μm that is equivalent to a film thickness formed by coating.

As a substrate, a resin or the like not decomposing during heating is used. When a resin is an amorphous resin for example, the difference in glass transition temperature between the amorphous resin and oxide glass is preferably within about 100° C. When a resin is a crystalline resin, the difference between the melting point of the crystalline resin and the glass transition temperature of oxide glass is preferably within 100° C. When the softening point of glass is lower than the softening point of a resin or the like and the temperature difference is large, it is possible to form a laminate while only the glass softens and the resin or the like does not transform. When the softening point of glass is equal to the softening point of a resin or the like or the temperature difference is small, the resin or the like may possibly decompose during heating. Even on that occasion, when the softening point of the glass is sufficiently low, the resin or the like melts at a part touching the glass during the softening of the glass and adheres firmly to the glass and the adhesion can be enhanced. It is necessary however to adjust the heating time so as not to be excessively prolonged. As a resin, a synthetic resin such as a thermosetting resin or a thermoplastic resin is mostly used. As rubber, a resilient material, such as natural rubber or synthetic rubber, primarily comprising organic molecules is used. Any of a resin or rubber is acceptable as long as it hardly decomposes in a temperature region close to the softening temperature of glass.

Further, it is preferable that oxide glass in a laminate at least contains Ag₂O, V₂O₅, and TeO₂ and the total content of Ag₂O, V₂O₅, and TeO₂ is equal to or more than 75% by mass. Ag₂O and TeO₂ are components contributing to the reduction of a softening point and the softening point of glass according to the present invention nearly corresponds to the content of Ag₂O and TeO₂. V₂O₅ inhibits metallic Ag from precipitating from Ag₂O in glass and contributes to the improvement of the thermal stability of the glass. By adopting such a composition range, it is possible to reduce the softening point (the peak temperature of a second endothermic peak at an elevated temperature process in DTA) of glass to a temperature of 320° C. or lower and secure sufficient thermal stability.

As concrete compositions of oxide glass, it is preferable to contain Ag₂O of 10% to 60% by mass, V₂O₅ of 5% to 65% by mass, and TeO₂ of 15% to 50% by mass. Here, in the present invention for example, 10% to 60% by mass means equal to or more than 10% by mass to equal to or less than 60% by mass. Since metallic Ag is inhibited from precipitating from Ag₂O by the addition of V₂O₅, the quantity of Ag₂O can be increased, a softening point lowers further, and the chemical stability (humidity resistance, for example) of glass improves. By adopting such a composition range, it is possible to secure a better humidity resistance than a conventional lead-free low-melting glass.

If an Ag₂O content increases to more than 2.6 times a V₂O₅ content, a softening point Ts does not so much drop even though Ag₂O is added further and moreover glass tends to crystallize. Consequently, it is preferable to control an Ag₂O content to equal to or less than 2.6 times a V₂O₅ content.

Further, oxide glass has a particularly excellent humidity resistance when the oxide glass contains Ag₂O of 10% to 60% by mass, V₂O₅ of 5% to 65% by mass, and TeO₂ of 15% to 50% by mass, the total content of Ag₂O, V₂O₅, and TeO₂ is equal to or more than 75% by mass, and the sum of an Ag₂O content and a V₂O₅ content is 40% to 80% by mass.

The softening point of glass having such a composition range can be reduced to a temperature not higher than the temperature at which a resin or the like decomposes, hence it is possible to soften and fluidize glass and form a dense and continuous film by coating a substrate containing a resin or the like having a high thermal resistance with the glass and heating the glass, and thus a laminate being formed by compounding the resin or the like and the glass and having a high gas barrier property can be obtained.

A method for manufacturing oxide glass according to the present invention is not particularly limited and the oxide glass can be manufactured by charging a raw material produced by blending and mixing various oxides coming to be the raw material into a platinum crucible, heating the raw material to 900° C. to 950° C. at a heating rate of 5° C./min to 10° C./min in an electric furnace, and retaining the temperature for several hours. It is desirable to stir the material during the retention in order to obtain homogeneous glass. When the crucible is taken out from the electric furnace, it is desirable to pour the glass into a graphite mold or onto a stainless steel plate heated to about 150° C. beforehand in order to prevent moisture from being absorbed on the surface of the oxide glass.

Resin or rubber in the present invention is not particularly limited, either a crystalline substance or an amorphous substance can be used, and it is also possible to use not only one type but also several types in combination. For example, polyethylene, polyvinyl chloride, polypropylene, polystyrene, polyvinyl acetate, ABS resin, AS resin, acrylic resin, phenolic resin, polyacetal resin, polyimide, polycarbonate, modified polyphenylene ether (PPE), polybutylene terephthalate (PBT), polyarylate, polysulfone, polyphenylene sulfide, polyether ether ketone, polyimide resin, fluorine resin, polyamide-imide, polyether ether ketone, epoxy resin, polyester, Polyvinyl ester, fluorocarbon rubber, silicone rubber, acrylic rubber, etc. can be used. Here, it is preferable that the heatproof temperature of resin or rubber is as high as possible.

The present invention is hereunder explained further in detail on the basis of concrete examples. The present invention however is not limited to the examples taken up here and includes variations thereof. Further, the following improvements and modifications can be added.

A laminate according to the present invention can be used for an electric and electronic component, an organic EL element, an organic thin film solar battery, an organic transistor, etc.

### EXAMPLE 1

In the present example, glasses having various compositions are manufactured and the relationship between the softening point and the humidity resistance of each of the glasses is investigated.

### (Manufacturing of Glass)

The glasses (SPL-01 to 25) having the compositions shown in Table 1 are manufactured. The compositions in the table are represented by the mass percentages in oxide equivalent of the respective components. As the starting materials, oxide powder (99.9% purity) made by Kojundo Chemical Laboratory Co., Ltd. is used. In some samples, Ba (PO₃)₂ (barium phosphate, made by RASA Industries, Ltd.) is used as the Ba source and the P source.

Various types of the starting material powders are mixed with the mass percentages shown in Table 1 and put into a platinum crucible. An alumina crucible is used when the ratio of Ag₂O in a material is equal to or more than 40%, by mass. In the event of the mixing, a metal spoon is used and the mixing is carried out in the crucible in consideration of avoiding excessive humidity from being absorbed into the material powder.

The crucible containing each of the mixed material powders is placed in a glass fusing furnace and the mixed material powder is heated and melted. The temperature is raised at a heating rate of 10° C./min and the molten glass is retained at a setting temperature (700° C. to 900° C.) for one hour while stirred. Successively, the crucible is extracted from the glass fusing furnace and the glass is molded in a graphite mold heated to 150° C. beforehand. Successively, the molded glass is transferred to a stress relief furnace heated to a stress relief temperature beforehand, strain is removed by retaining the glass for one hour, and successively the glass is cooled to room temperature at a rate of 1° C./min. The glass cooled to room temperature is pulverized and the powder of the glass having a composition shown in the table is manufactured.

### (Evaluation of Softening Point)

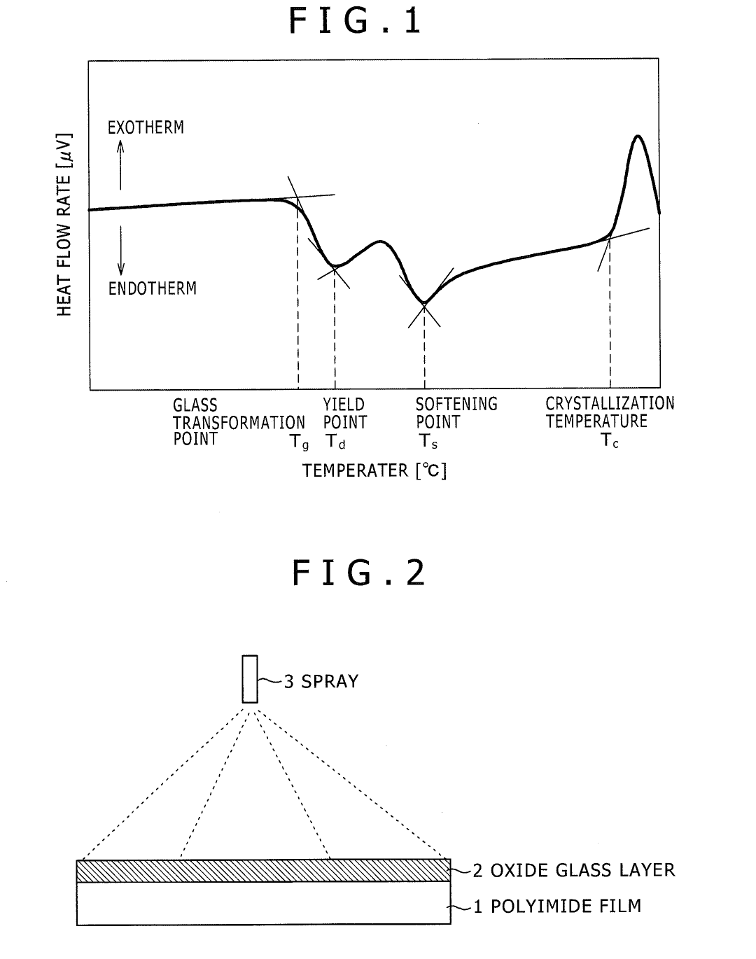

The softening points Ts of the glass powders obtained above are measured by differential thermal analysis (DTA). In the DTA measurement, the mass of each of a reference sample (α-alumina) and a measurement sample is set at 650 mg, each of the samples is heated at a heating rate of 5° C./min in the atmosphere, and the peak temperature of a second endothermic peak is obtained as a softening point Ts (refer to FIG. 1). The results are shown together in Table 1.

TABLE 1

| | | | | | | | | | Glass characteristic | | | |
|---|---|---|---|---|---|---|---|---|---|---|---|---|
| | | | | | | | | | temperature | | | |
| | | | | | | | | | Glass | | Glass | |
| Sample | Glass composition (% by mass) | | | | | | | | transition | Yield | softening | |
| No. | V₂O₅ | Ag₂O | TeO₂ | P₂O₅ | BaO | WO₃ | Fe₂O₃ | Sb₂O₃ | point | point | point | Remarks |
| SPL-01 | 30.0 | 30 | 30.0 | 4.8 | 5.2 | | | | 222 | 246 | 277 | |
| SPL-02 | 30.0 | 30 | 30.0 | 5.0 | | 5 | | | 230 | 246 | 284 | |
| SPL-03 | 25.0 | 30 | 30.0 | 4.8 | 5.2 | 5 | | | 223 | 245 | 285 | |
| SPL-04 | 25.0 | 30 | 30.0 | 7.2 | 7.8 | | | | 228 | 251 | 295 | |
| SPL-05 | 30.0 | 25 | 30.0 | 4.8 | 5.2 | 5 | | | 236 | 262 | 295 | |
| SPL-06 | 25 | 50 | 25 | | | | | | 204 | 228 | 273 | |
| SPL-07 | 30.0 | 30 | 30.0 | 5.0 | | | 5 | | 235 | 262 | 300 | |
| SPL-08 | 25.0 | 30 | 30.0 | 10.0 | | | 5 | | 266 | 291 | 320 | |
| SPL-09 | 25.0 | 30 | 30.0 | 5.0 | | 5 | 5 | | 249 | 272 | 315 | |
| SPL-10 | 25.0 | 30 | 30.0 | 5.0 | | 10 | | | 236 | 253 | 294 | |
| SPL-11 | 30.0 | 25 | 30.0 | 4.8 | 5.2 | 5 | | | 237 | 257 | 296 | |
| SPL-12 | 20.0 | 35 | 30.0 | 4.8 | 5.2 | 5 | | | 204 | 225 | 269 | SYC-12 |
| SPL-13 | 17.0 | 38 | 30.0 | 4.8 | 5.2 | 5 | | | 197 | 214 | 260 | SYC-14 |
| SPL-14 | 17.0 | 43 | 30.0 | | 5.0 | 5 | | | 177 | 192 | 233 | SYC-15 |
| SPL-15 | 20.0 | 45 | 35.0 | | | | | | 163 | 172 | 208 | SYC-16 |
| SPL-16 | 17.0 | 43 | 40.0 | | | | | | 169 | 180 | 213 | |
| SPL-17 | 40.0 | 20 | 40.0 | | | | | | 218 | 233 | 266 | |
| SPL-18 | 20.0 | 45 | 30.0 | | | 5 | | | 169 | 182 | 216 | |
| SPL-19 | 45.0 | 20 | 30.0 | | | 5 | | | 224 | 232 | 262 | |
| SPL-20 | 40.0 | 25 | 35.0 | | | | | | 212 | 224 | 259 | |
| SPL-21 | 18.0 | 43 | 34.0 | | 5.0 | | | | 167 | 183 | 221 | SYC-24 |
| SPL-22 | 40.0 | 35 | 25.0 | | | | | | 235 | 255 | 300 | |
| SPL-23 | 30 | 45 | 25 | | | | | | 216 | 236 | 281 | |
| SPL-24 | 0.0 | 40 | 40.0 | 20.0 | | | | | 221 | 240 | 270 | Ag—Te—P |

### EXAMPLE 2

A laminate is manufactured through the following procedure by using a glass obtained in Example 1. SPL-15 having the lowest softening point in the glasses manufactured in Example 1 is pulverized into the average grain size of 0.5 μm or smaller, successively a resin binder and a solvent are mixed, and thus slurry for spray atomization is manufactured. Nitrocellulose is used as the resin binder and butyl carbitol acetate is used as the solvent.

An image of a process of forming an oxide layer on a polyimide film is shown in FIG. 2. A film is formed by atomizing the obtained slurry onto the polyimide film 1 having a thickness of 12 μm with a spray 3, heated to 250° C. and retained for 10 min in a furnace, and successively cooled naturally, and thus an oxide glass layer 2 is formed on the polyimide film 1. The thickness of the oxide glass layer 2 is 1.2 μm.

As comparative examples, a PET film and an inorganic material vapor deposition layer formed by depositing an SiOx film (x represents 2 or smaller) having a thickness of 50 nm on a PET film by a vacuum vapor deposition method are prepared and used as gas permeability evaluation samples. The oxygen permeation rate and the water vapor permeation rate of each of the obtained laminated films are evaluated.

### (1) Measurement of Oxygen Permeation Rate

Oxygen permeation rates are measured under the condition of a pressure difference of 0.1 MPa by using the gas barrier films manufactured as stated above and using an oxygen permeation rate measurement device (OX-TRAN (R) 2/20) made by MOCON Inc. in USA under the conditions of a temperature of 30° C. and a humidity of 90% RH. The measurement limit of the device is 0.01 cc/m²/day.

### (2) Measurement of Water Vapor Permeation Rate

Water vapor permeation rates are measured under the condition of a pressure difference of 0.1 MPa by using the gas barrier films manufactured as stated above and using a moisture permeation rate measurement device (PERMATRAN (R) 2/20) made by MOCON Inc. in USA under the conditions of a temperature of 30° C. and a humidity of 90% RH. The measurement limit of the device is 0.01 g/m²/day.

The measurement results are shown in Table 2. The oxygen transmittance and the water vapor transmittance of the laminate according to the present invention are equal to or less than the measurement limit of the device. On the other hand, it is shown from the measurement results that: the oxygen permeation rate and the water vapor permeation rate of the PET substrate are very high; and a gas barrier property is improved considerably by forming the SiOx vapor deposition film on the PET substrate but a trifle amount of gas permeates. This is because the thickness of the inorganic material layer such as SiOx is thin. The laminate according to the present invention is obtained by baking a thick film formed by spray atomization and it is shown that the thickness of the oxide layer is as thick as 1.2 μm and hence the excellent gas barrier property is exhibited.

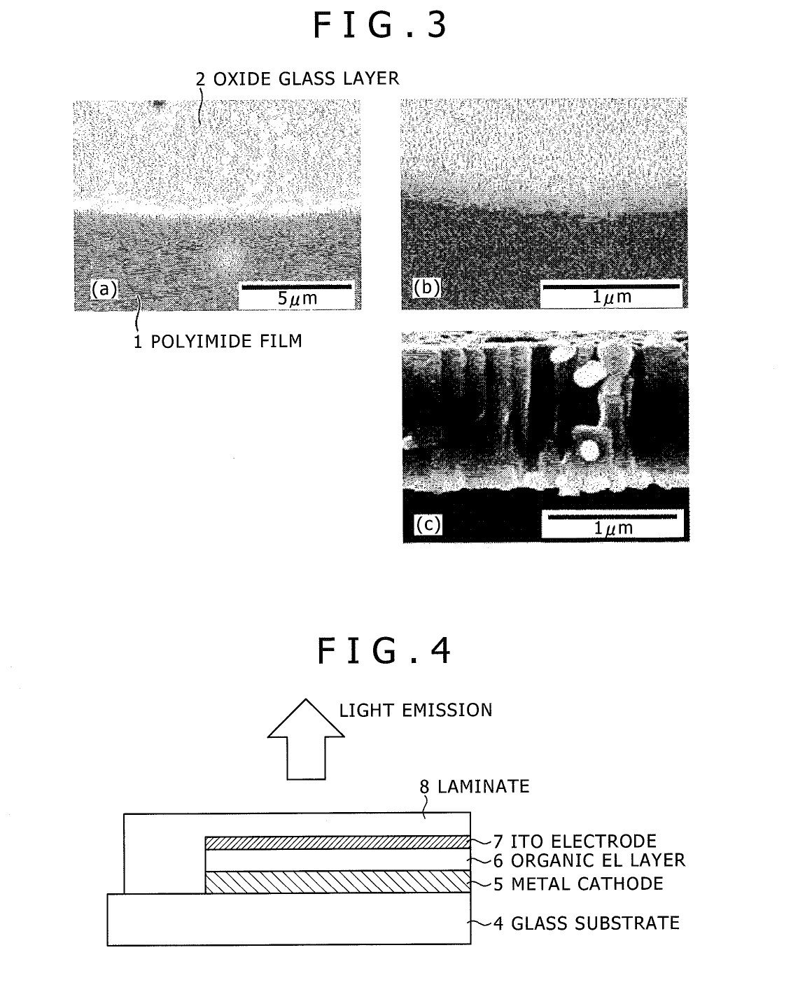

The difference in gas barrier property between the laminate according to the present example and the laminates according to the comparative examples is hereunder explained in reference to the SEM images of the fine structures of the films. The interfaces between the glasses and the substrates in the present example manufactured as stated above are observed by SEM. (a) and (b) in FIG. 3 represent SEM images of the film structure of the laminate according to the present example and (c) in FIG. 3 represents an SEM image of the film structure of the laminate according to a comparative example. Whereas defects exist in the longitudinal direction of the oxide glass layer 2 in (c) of FIG. 3, such defects are not observed in the present example. In (c) of FIG. 3, the sizes of the defects are about the values obtained by dividing the thickness of the film by tens to hundreds, hence the gas barrier property is not perfect, and the oxygen permeability is about 0.9 to 1.5 cc/m²/day. On the other hand, in the laminate according to the present example, the oxide glass layer 2 contains V, Ag, and Te having low softening points, undergoes a molten state and thus is dense, and hence does not have defects allowing a gas to permeate. The thickness of the oxide glass layer 2 of a laminate can be adjusted to any thickness by a coating method of slurry or paste and is about 500 nm to 50 μm when slurry is atomized by spraying and about 50 μm to 500 μm when paste is used for printing. The thickness is overwhelmingly thicker than the film thickness of a comparative example, moreover the film structure is dense, and hence the gas barrier property is significantly good.

TABLE 2

| | | | | Film | | |
|---|---|---|---|---|---|---|
| | | | | total | Oxygen | Water vapor |
| | | Film | | thickness | transmittance | transmittance |
| | | thickness | | (μm) | (cc/m²/day) | (g/m²/day) |
| Present | Polyimide/SPL-22 | 1.2 | μm | 13.2 | Measurement | Measurement |
| invention | film laminate | | | | limit or less | limit or less |
| Comparative | PET film | ~ | | 12 | 194 | 41 |
| example 1 | | | | | | |
| Comparative | PET film/SiOx | 50 | nm | 12.1 | 2 | 2.2 |
| example 2 | vapor deposition | | | | | |
| | film | | | | | |

### EXAMPLE 3

An organic EL element having a simple structure is manufactured by using a laminate manufactured in Example 2. A part of the organic EL element used in the present experiment is shown in FIG. 4. A metal cathode 5, an organic EL layer 6 (green), and an ITO electrode layer 7 are stacked on a glass substrate 4. The organic EL element is sealed by attaching a laminate 8 according to the present invention cut out to the size of 40 mm×50 mm with an adhesive onto the ITO electrode of the organic EL element (15 mm×20 mm) in a glove box of a nitrogen atmosphere at the atmospheric pressure (0.1 MPa) and thus the EL element A is manufactured. Likewise, the organic EL elements sealed by the films of the comparative examples 1 and 2 in table 2 are used as the EL elements B and C.

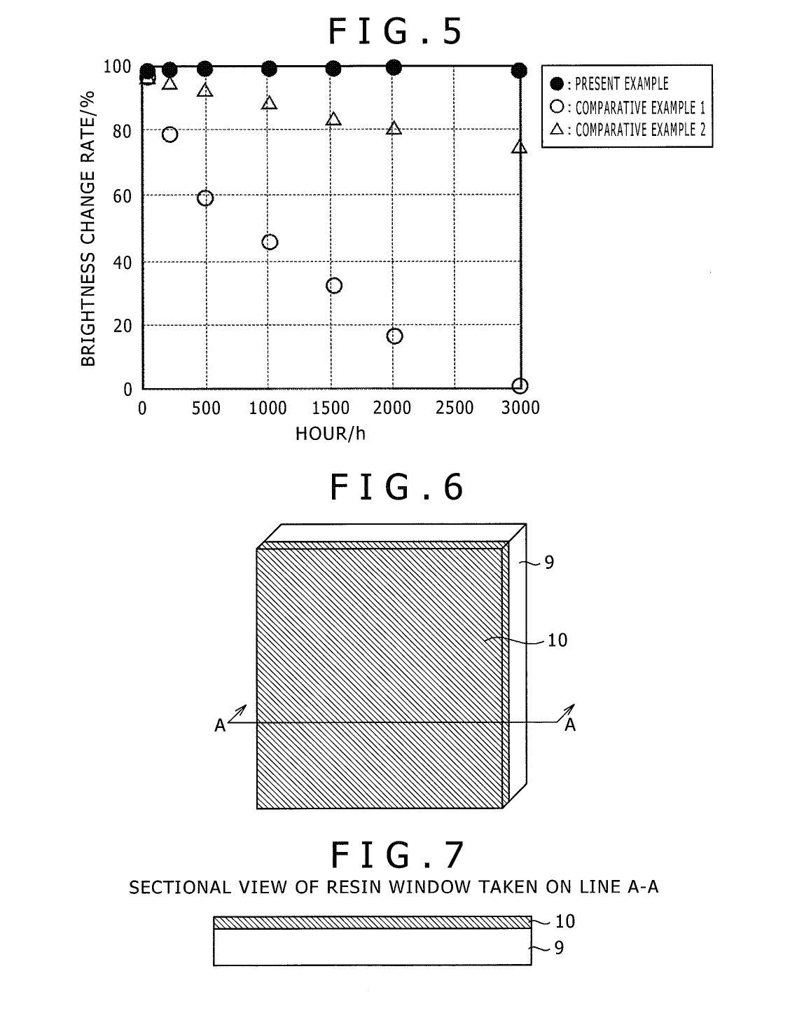

The organic EL elements are placed in a damp air at an atmospheric temperature of 50° C. and a relative humidity of 90%, connected to an alternating-current source of 100 V and 400 Hz, and lighted continuously and the brightness is measured. The results of setting the brightness immediately after the start of experiment at 100% and measuring the chronological change of the brightness are shown in FIG. 5. It is confirmed that the brightness deterioration rate of the EL element A is zero in comparison with the EL elements B and C for comparison. That is, it is understood that the reliability of an organic EL element can be improved by using a laminate according to the present example as a film material for sealing.

### EXAMPLE 4

FIG. 6 is a front view showing a resin window according to the present example. FIG. 7 is a sectional view of the resin window taken on line A-A′ of FIG. 6. As shown in FIGS. 6 and 7, the resin window according to the present example comprises a polycarbonate substrate 9 and an oxide glass layer 10 formed on the surface on the room exterior side.

A resin window according to the present example is manufactured through the following procedure. Firstly, a polycarbonate-made resin window (100 mm×100 mm×4 mm in thickness) is formed by injection molding. Successively, as shown in FIG. 2, slurry of oxide glass fine particles is atomized to the resin window by splaying and dried and thus a fine particle layer of the oxide glass is formed. As the oxide glass, three types of SPL-12, SPL-15, and SPL-21 are used.

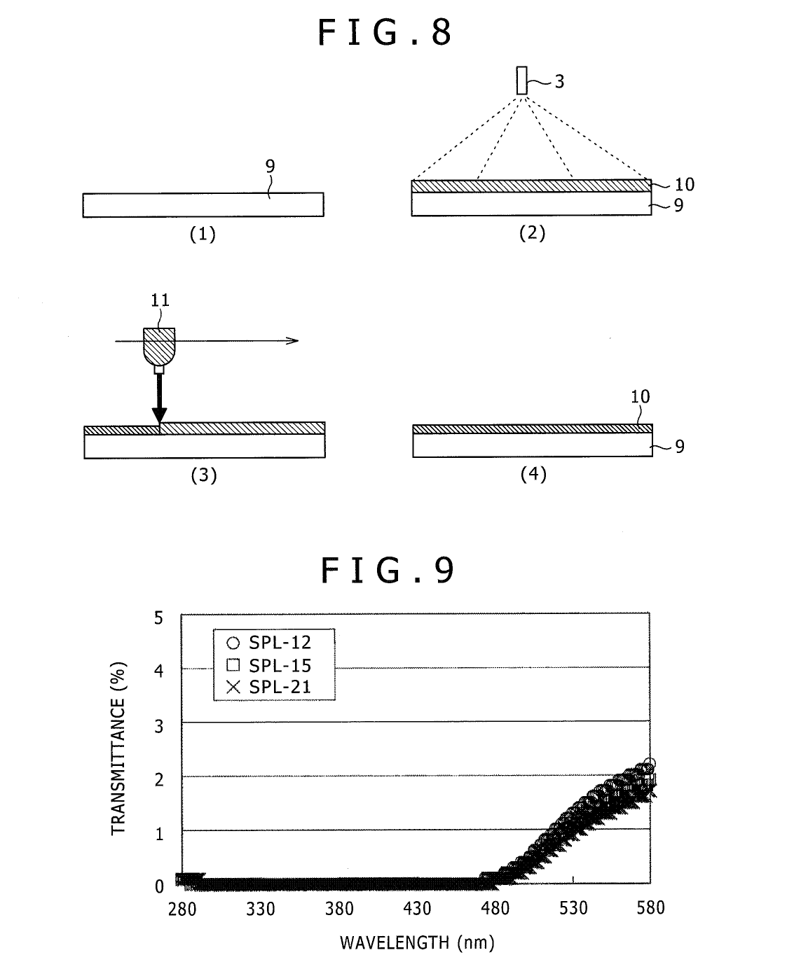

Although the fine particles of the oxide glass are to soften and fluidize and to turn into a continuous single-layered oxide glass layer thereafter, the heatproof temperature of the polycarbonate is 180° C. and hence the oxide glass fine particle layer and the resin window cannot be heated simultaneously in an electric furnace. On such an occasion, by irradiating and heating the oxide glass fine particle layer on the resin window surface with a laser, the fine particles of the oxide glass soften and fluidize and turn into a continuous single-layered oxide glass layer without damaging the resin window. In the present example, the oxide glass fine particle layer is irradiated with a laser under the conditions of an output of 20 W and a scanning speed of 50 mm/s by using a semiconductor laser 11 having a wavelength of 808 nm and the continuous single-layered oxide glass layer is formed. The thickness of the oxide glass film of each of SPL-12, SPL-15, and SPL-21 thus manufactured is 9 μm. The manufacturing process of such a resin window is shown in FIG. 8.

The specific gravity of the manufactured resin window is nearly equal to the specific gravity of polycarbonate and is 1.2 g/cm³. The specific gravity of ordinary window glass is 2.4 g/cm³ and the weight of the resin window is about a half thereof.

A transmittance is measured with an ultraviolet to visible light spectrophotometer (U-4100 made by Hitachi, Ltd.) in order to verify how much ultraviolet light is shielded by the oxide glass layer of a manufactured resin window. The wavelength range is set at 240 to 2,600 nm and the scanning speed is set at 300 nm/min in the measurement. FIG. 9 shows the measurement results of the transmittances. In any of the oxide glass layers, the transmittance in the range of 240 to 400 nm is nearly zero and a very good ultraviolet light shielding function is exhibited.

When a resin window having the above structure is irradiated with sunlight, the ultraviolet light having the wavelengths of 240 to 400 nm is shielded by the function of the oxide glass layer 10 and a resin material is protected from the ultraviolet light.

In general, the sunlight having the wavelength region of 280 to 400 nm in the spectral band largely influences various materials, bonded main chains are cut gradually from a surface when a polycarbonate single body is irradiated with sunlight, and a powdering phenomenon (chalking) occurs continuously and progresses to a depth. It is said that the dissociation sensitive wavelength (nm) of a C-C bond in polycarbonate is 280 to 310 and a resin window comprising polycarbonate is materialized by forming an oxide glass layer for shielding the ultraviolet light in the wavelength region.

Although a window in a building is described in the present example, the present invention can be applied also to a resin window of a side or rear window of an automobile or a resin window in various kinds of vehicle bodies other than an automobile.

### EXAMPLE 5

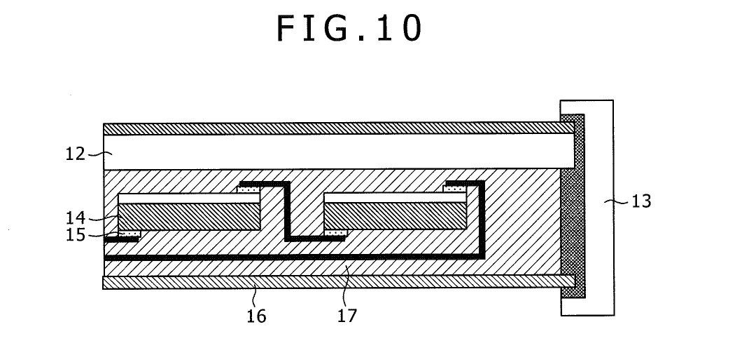

The structure of a solar battery module wherein a resin window of Example 4 is used as a substitute for a front glass is shown in FIG. 10. The solar battery module in FIG. 10 comprises a resin window 12 having an oxide glass layer that is a laminate according to the present example and is installed on the incidence side of sunlight, a sealing material 13 comprising a vanadate glass composition, solar battery cells (solar battery elements) 14, aluminum electrodes 15 and a back sheet 16 using vanadate glass. Convexo-concave can be formed on the sunlight incidence side of the resin window 12 and exhibits the effect of antireflection. As a method for forming convexo-concave, there is a nanoimprint method or the like.

The resin window 12 is manufactured by the manufacturing method completely identical to the method for manufacturing the resin window in Example 4, the substrate is polycarbonate, and an oxide glass layer (SPL-15) 9 μm in thickness is formed on the outer surface thereof. Although polycarbonate is used as the substrate, it is also possible to use a transparent substrate, such as acryl, polyester, or polyethylene fluoride, not interfering with the incidence of sunlight. Those are called lightweight cover glass.

As a solar battery cell 14, various solar battery elements including a monocrystalline silicon solar battery, a polycrystalline silicon solar battery, a thin film chemical compound semiconductor solar battery; an amorphous silicon solar battery, etc. can be used. With regard to the solar battery cell 14, one cell or plural cells are installed in a solar battery module and, in the case of plural cells, the cells are electrically connected to each other with an interconnector through an aluminum electrode 15 using vanadate glass. Further, as a back sheet 16, a metal layer or a plastic film layer can be used in order to secure weather resistance, a high insulating capacity, and strength.

Many solar battery cells 14 are connected in series, installed between a resin window 12 and aback sheet 16, and attached with an EVA sheet 17. The periphery is fixed with an aluminum frame 13 and a solar battery module is manufactured.

The specific gravity of a resin window is about 1.2 g/cm³ and is about a half of the specific gravity 2.4 g/cm³ of ordinary glass. In a solar battery module, the weight reduction of 40% can be attained by using a resin window having an oxide glass layer according to the present example. As a result, the cost of a support can be reduced by 34% and further the cost of construction can also be reduced.

### EXPLANATION OF REFERENCE NUMERALS

1 Polyimide film
2, 10 Oxide glass layer
3 Spray
4 Glass substrate
5 Metal cathode
6 Organic EL layer
7 ITO electrode
8 Laminate
9 Polycarbonate substrate
11 Semiconductor laser
12 Resin window
13 Aluminum frame
14 Solar battery cell
15 Aluminum electrode
16 Back sheet
17 EVA sheet

1-3. (canceled)

4. A laminate comprising a substrate containing resin or rubber and oxide glass formed at least on one surface of the substrate, wherein the oxide glass contains Ag₂O, V₂O₅, and TeO₂ and the total content of Ag₂O, V₂O₅, and TeO₂ is equal to or more than 75% by mass, and the oxide glass softens and fluidizes at a temperature equal to or lower than the softening temperature of the substrate and adheres to the substrate.

5. A laminate according to claim 4, wherein the oxide glass contains Ag₂O of 10% to 60% by mass, V₂O₅ of 5% to 65% by mass, and TeO₂ of 15% to 50% by mass.

6. A laminate according to claim 5, wherein the Ag₂O content is equal to or less than 2.6 times the V₂O₅ content in the oxide glass.

7. (Orignal) A laminate according to claim 5, wherein the sum of the Ag₂O content and the V205 content is 40% to 80% by mass in the oxide glass.

8. (canceled)

9. A laminate according to claim 4, wherein the oxide glass softens and fluidizes by laser irradiation and adheres to the substrate.

10. An organic EL element that uses a laminate according to claim 4 as a sealing sheet.

11. A window that uses a laminate according to claim 4.

12. A solar battery module that uses a laminate according to claim 4 as a sealing sheet.
